(19) United States
(12) Patent Application Publication
(10) Pub. No.: US 2016/0374222 A1
(43) Pub. Date: Dec. 22, 2016

(54) CARD GUIDE FOR A PRINTED CIRCUIT BOARD

(71) Applicant: Tyco Electronics Corporation, Berwyn, PA (US)

(72) Inventor: David Allison Trout, Lancaster, PA (US)

(21) Appl. No.: 14/744,206

(22) Filed: Jun. 19, 2015

(51) Int. Cl. H05K 7/14

(52) U.S. Cl. CPC H05K 7/1427

(57) ABSTRACT

A card guide is provided for holding a printed circuit board. The card guide includes a body extending a length from a front end to a rear end. The body includes a slot. The slot is configured to receive an edge of printed circuit board therein. A first spring member extends into the slot. The first spring member is configured to engage in physical contact with the edge of the printed circuit board within the slot such that the first spring number biases the printed circuit board in a first direction. A second spring member extends into the slot. The second spring member is configured to engage in physical contact with the edge of the printed circuit board within the slot such that the second spring member biases the print circuit board in a second direction that extends approximately perpendicular to the first direction.

### BACKGROUND OF THE INVENTION

The subject matter herein relates generally to card guides that hold printed circuit boards within electronic systems.

Within at least some known electronic systems, one or more printed circuit boards are held within an enclosure, such as a rack, a frame, a housing, and/or the like. Printed circuit boards are sometimes held within the enclosure using two or more card guides. A card guide includes a slot that holds the edge of a corresponding printed circuit board therein. The slots may guide the printed circuit board into a predetermined position within the enclosure. For example, card guides may guide one or more connectors of the corresponding print circuit board into electrical connection with one or more corresponding mating connectors as the printed circuit board is assembled into the electronic system.

Printed circuit boards are fabricated with tolerances for the thickness dimension of the board as well as for one or more dimensions between edges (e.g., the length, width, and/or the like) of the board. Hole patterns of printed circuit boards for connectors and/or other components may also have tolerances, for example relative to one or more edges of the printed circuit board. The slots of the card guides are therefore sized such that the edges of the board fit relatively loosely therein to enable the printed circuit board to shift to accommodate (i.e., take up) the tolerances. The relatively loose fit of the edges of the printed circuit board within the slots of the card guides enables the printed circuit board to be installed into the predetermined position within the enclosure. For example, the printed circuit board may shift within the slots of the card guides to align one or more connectors of the board for mating with the corresponding mating connector(s).

The printed circuit board and/or components (e.g., connectors and/or the like) thereof may include tapered guide devices (e.g., guide pins, guide posts, guide openings, guide slots, and/or the like) that shift the printed circuit board within the slots as the printed circuit board is installed into the enclosure using the card guides. But, as the printed circuit board is inserted into the card guides, the weight of the board initially shifts the board against one or more sides of one or more of the card guides, which may include a top, bottom, and/or side of the slot of one or more of the card guides depending on the orientation of the printed circuit board. Accordingly, the tapered guide devices may require a relatively large lead-in (e.g., amount of taper) to shift the printed circuit board sufficiently from the side(s) of the card guide(s) to a position that accommodates the tolerances (e.g., a position that enables one or more connectors to mate with one or more corresponding mating connectors). The relatively large lead-in of the guide devices increases the size of the guide devices, which may increase cost, may increase the size of the printed circuit board and/or the enclosure, may decrease the number of printed circuit boards that can be held by the enclosure, and/or the like. In some circumstances, one or more constraints (e.g., a maximum size of the guide devices, the value of the tolerance, and/or the like) of the electronic system prevent the guide devices from having the size that provides a sufficiently large lead-in to accommodate the tolerances. For example, tolerance differences may prevent the guide devices of printed circuit boards that mate directly together in a perpendicular orientation (i.e., a direct plug orthogonal (DPO) board orientation) from having a sufficiently large lead-in to accommodate the tolerances.

### BRIEF DESCRIPTION OF THE INVENTION

In an embodiment, a card guide is provided for holding a printed circuit board within an enclosure. The card guide includes a body extending a length from a front end to a rear end. The body includes a slot extending through at least a portion of the length of the body. The slot is configured to receive an edge of printed circuit board therein. A first spring member extends into the slot. The first spring member is configured to engage in physical contact with the edge of the printed circuit board within the slot such that the first spring number biases the printed circuit board in a first direction. A second spring member extends into the slot. The second spring member is configured to engage in physical contact with the edge of the printed circuit board within the slot such that the second spring member biases the print circuit board in a second direction that extends approximately perpendicular to the first direction.

In an embodiment, a card guide is provided for holding a printed circuit board having an edge that includes opposite first and second sides and an edge surface that extends between the first and second sides. The card guide includes a body extending a length from a front end to a rear end. The body includes a slot extending through at least a portion of the length of the body. The slot is configured to receive the edge of the printed circuit board therein. The slot includes opposing first and second side wall surfaces and a bottom wall surface that extends between the first and second side wall surfaces. First and second spring members extend along the first and second side wall surfaces, respectively, of the slot. The first and second spring members are configured to exert a spring force on the first and second sides, respectively, of the edge of the printed circuit board. A third spring member extends along the bottom wall surface of the slot. The third spring member is configured to exert a spring force on the edge surface of the edge of the printed circuit board.

In an embodiment, an assembly includes a printed circuit board having opposite edges, and first and second card guides. Each of the first and second card guides includes a slot configured to receive a corresponding one of the edges of the printed circuit board therein. First spring members extend within the slot and are configured to exert opposing spring forces on the corresponding edge of the printed circuit board that cooperate to approximately center the corresponding edge of the printed circuit board within the slot. A second spring member extends within the slot and is configured to exert a spring force on the corresponding edge of the printed circuit board. The spring forces exerted by the second spring members of the first and second card guides oppose each other and cooperate to approximately center the printed circuit board between the first and second card guides.

### BRIEF DESCRIPTION OF THE DRAWINGS

FIG. 1 is a perspective view of an embodiment of an electronic system.

FIG. 2 is perspective view of an embodiment of a card guide of the electronic system shown in FIG. 1.

FIG. 3 is a plan view of the card guide shown in FIG. 2.

FIG. 4 is a cross-sectional view of the card guide shown in FIGS. 2 and 3 taken along line 4-4 of FIG. 3.

FIG. 5 is an elevational view of a portion of the electronic system shown in FIG. 1 illustrating an exemplary printed circuit board held by the card guide shown in FIGS. 2-4.

FIG. 6 is an elevational view of the electronic system shown in FIG. 1 illustrating exemplary printed circuit boards as held by a plurality of the card guides shown in FIGS. 2-5.

### DETAILED DESCRIPTION OF THE INVENTION

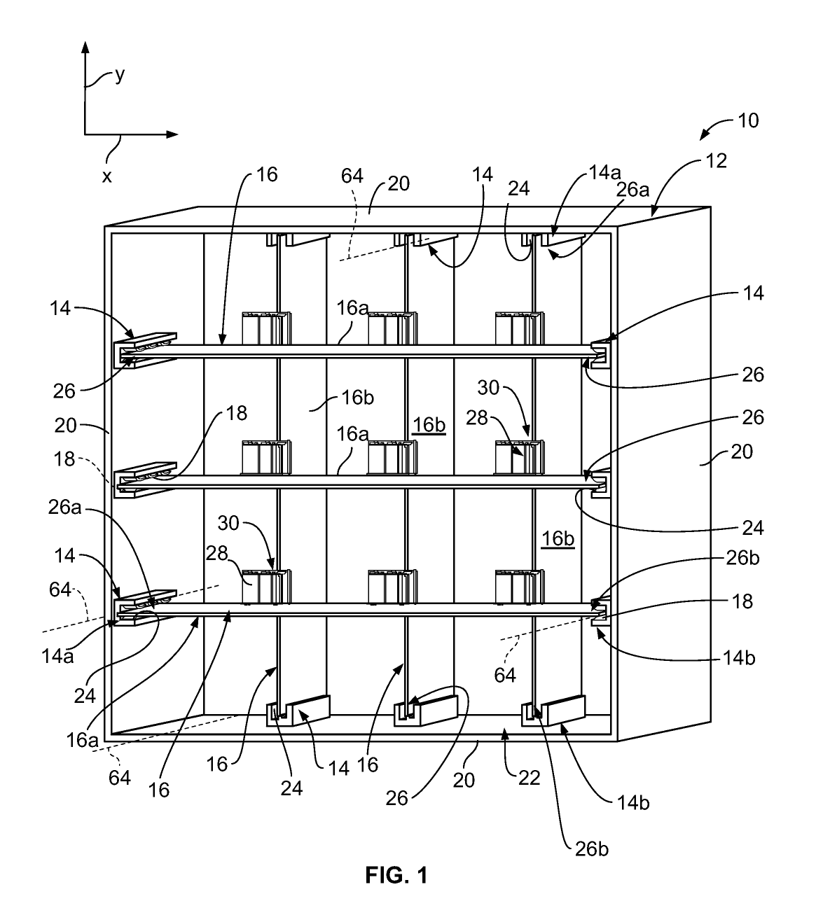

FIG. 1 is a perspective view of an embodiment of an electronic system 10. The electronic system 10 includes an enclosure 12, card guides 14, and printed circuit boards 16. The printed circuit boards 16 are held within the enclosure 12 by the card guides 14. The enclosure 12 includes one or more side walls 20 that define an interior chamber 22 of the enclosure 12. The card guides 14 are mounted to interior sides of the side walls 20 such that the card guides 14 extend within the interior chamber 22. The card guides 14 include slots 24 that hold edges 26 of the printed circuit board 16 therein. In the illustrated embodiment, a pair of card guides 14 is used to hold each printed circuit board 16. Specifically, a first card guide 14a of each pair holds an edge 26a of the corresponding printed circuit board 16, and a second card guide 14b of the pair holds the opposite edge 26b of the corresponding printed circuit board 16, as is shown in FIG. 1.

As will be described in more detail below, the card guides 14 include spring members 18 that approximately center the corresponding printed circuit board 16 along two different axes (e.g., the x and y axes) that are not approximately parallel with each other.

In the illustrated embodiment, the printed circuit boards 16 are arranged within the interior chamber 22 of the enclosure 12 with some of the printed circuit boards 16a oriented approximately horizontally and others of the printed circuit boards 16b oriented approximately vertically. Moreover, the printed circuit boards 16a are electrically connected to the printed circuit board 16b using respective electrical connectors 28 and 30 of the printed circuit boards 16a and 16b. In the illustrated embodiment, the printed circuit boards 16a and 16b interconnect with a direct plug orthogonal (DPO) board orientation, but any other type, orientation, and/or the like of connection may be additionally or alternatively used in other embodiments. Moreover, in some embodiments, one or more of the printed circuit boards 16a and/or 16b is not connected to one or more others of the printed circuit boards 16a and/or 16b.

The pattern of the printed circuit boards 16a and 16b within the interior chamber 22 of the enclosure is meant as exemplary only. The electronic system 10 is not limited to the pattern shown and described herein. Rather, any other pattern may be used in other embodiments. For example, each printed circuit board 16 may have any orientation within the interior chamber 22 of the enclosure 12, and each printed circuit board 16 may have any orientation relative to any other printed circuit board 16 (whether or not the printed circuit board 16 is connected to the other printed circuit board 16). The electronic system 10 may include any number of the printed circuit boards 16. In some embodiments, all of the printed circuit boards 16 are oriented approximately horizontally within the interior chamber 22 of the enclosure 12, while in other embodiments all of the printed circuit boards 16 are oriented approximately vertically within the interior chamber 22 of the enclosure 12. Any number of card guides 16 may be used to hold a single printed circuit board 16.

The enclosure 12 is not limited to the structure, geometry, and/or the like shown herein. Rather, the enclosure 12 additionally or alternatively may have any other structure, geometry, and/or the like. For example, although shown as being a rack, additionally or alternatively the enclosure may be a frame, a housing, and/or the like. In addition or alternatively to the rectangular shape shown herein, the enclosure 12 may include any other shape, for example. Moreover, and for example, the enclosure 12 may include any number of the side walls 20. A printed circuit board 16 and one or more card guides 16 may be referred to herein as an “assembly”.

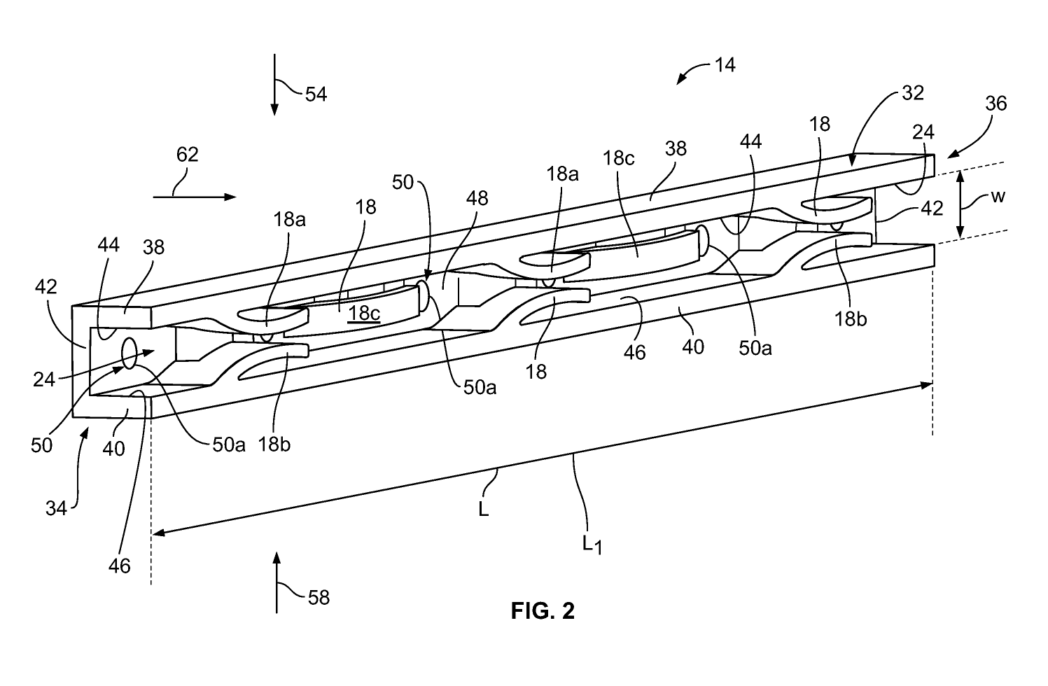

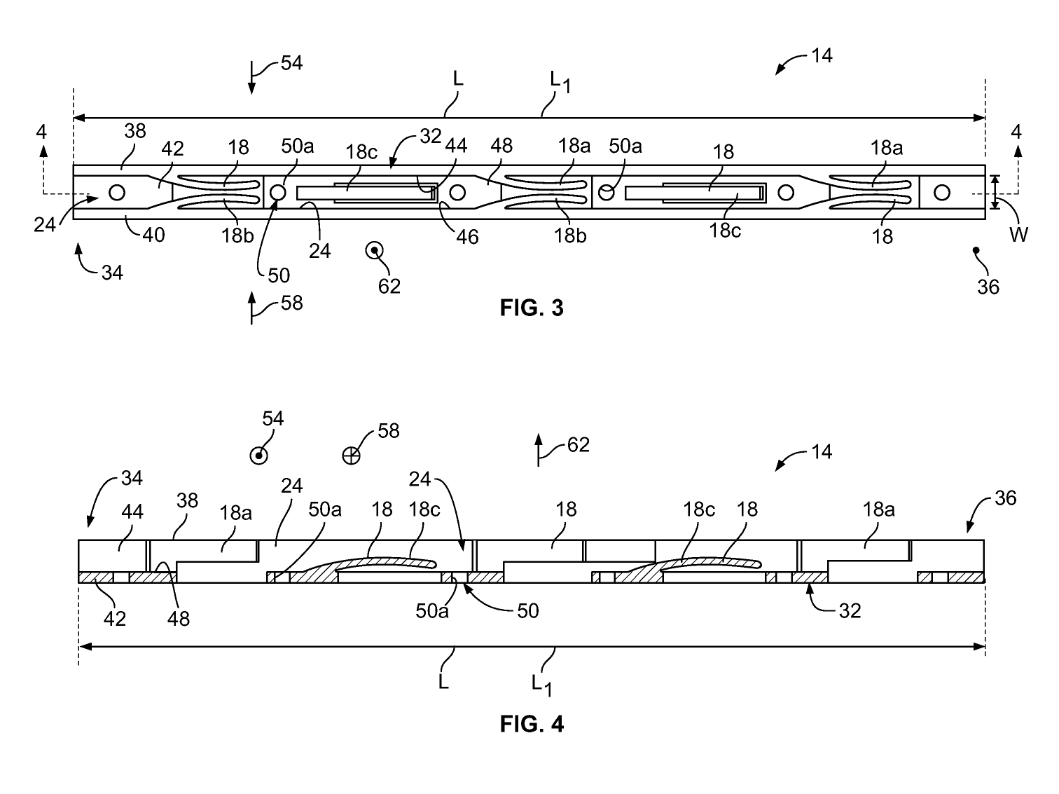

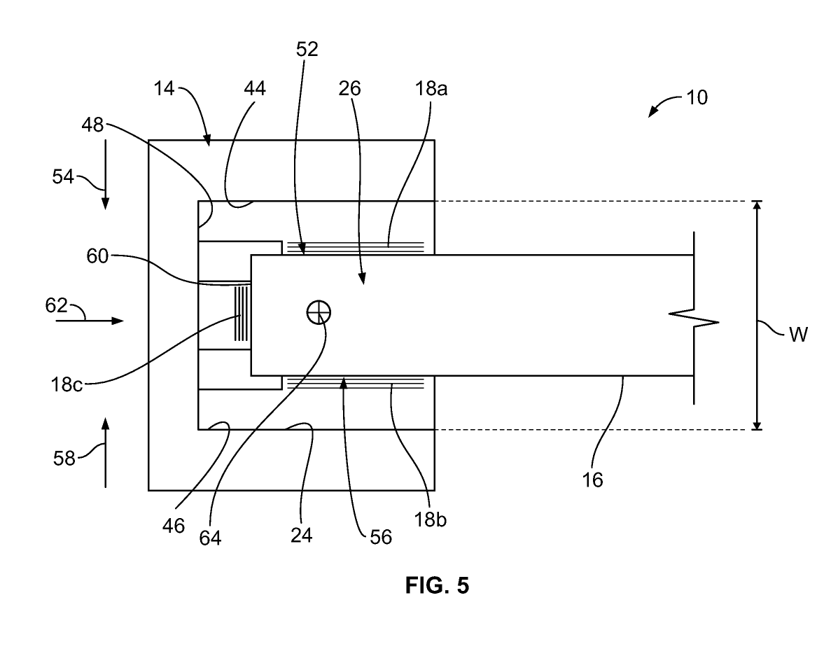

FIG. 2 is perspective view of an embodiment of a card guide 14. FIG. 3 is a plan view of the card guide 14. FIG. 4 is a cross-sectional view of the card guide 14 taken along line 4-4 of FIG. 3. Referring now to FIGS. 2-4, the card guide 14 includes a body 32 that extends a length L from a front end 34 to a rear end 36. The body 32 includes the slot 24, which as described above is configured to receive the corresponding edge 26 (shown in FIGS. 1 and 5) of the corresponding printed circuit board 16 (shown in FIGS. 1, 5, and 6) therein. The slot 24 extends a length L₁ through at least a portion of the length L of the body 32. In the illustrated embodiment, the slot 24 extends entirely through the length L of the body 32 (i.e., extends through the ends 34 and 36 and entirely through the body 32 therebetween such that the lengths L and L₁ are approximately equal). The slot 24 may extend through any amount of the length L of the body 32, whether or not the slot 24 extends through the front end 34 or the rear end 36. The slot 24 may extend through (i.e., be open at) at least one of the ends 34 or 36 to enable the edge 26 of the corresponding printed circuit board 16 to be loaded therein.

The body 32 of the card guide 14 includes opposing side walls 38 and 40, and a bottom wall 42 that extends between (i.e., interconnects) the side walls 38 and 40. The side wall 40 is not shown in FIG. 4. As shown in FIGS. 2 and 3, the lengths of the bottom wall 42 and the side walls 38 and 40 extend along the length L of the body 32. The bottom wall 42 and the side walls 38 and 40 define the slot 24. Specifically, the side wall 38, the side wall 40, and the bottom wall 42 include respective surfaces 44, 46, and 48 that define the slot 24. The side wall surface 46 is not shown in FIG. 4. The lengths of the bottom wall surface 48 and the side wall surfaces 44 and 46 extend along the length L of the body 32. The slot 24 has a width W defined between the side wall surfaces 44 and 46 (i.e., defined from the side wall surface 44 to the side wall surface 46). The width W is not visible in FIG. 4. Each of the side wall surfaces 44 and 46 may be referred to herein as a “first” and/or a “second” side wall surface.

The card guide 14 includes one or more mounting components 50 for mounting the card guide 14 to the side walls 20 (shown in FIG. 1) of the enclosure 12 (shown in FIG. 1). In the illustrated embodiment, the mounting components 50 include openings 50a that extend through the bottom wall 42 of the body 32. The openings 50a enable the card guide 14 to be mounted to the corresponding side wall 20 using mounting hardware such as, but not limited to, threaded fasteners and or the like. In addition or alternatively to the openings 50a, any other type of mounting component may be used, such as, but not limited to, a snap-fit arrangement, an interference-fit arrangement, a clamp, and/or the like.

The body 32 of the card guide 14 may be fabricated using any process(es), such as, but not limited to, molding, casting, machining, printing, and/or the like. The body 32 of the card guide 14 may be fabricated from any material(s), such as, but not limited to, a polymer, a plastic, a metal, a composite, and/or the like. In the illustrated embodiment, the body 32 of the card guide 14 is fabricated from one or more materials (such as, but not limited to, a polymer, a plastic, a composite, and/or the like) such that the body 32 is generally dielectric (i.e., electrically non-conductive). In other embodiments, the body 32 of the card guide 14 is fabricated from one or more materials (such as, but not limited to, a metal and/or the like) such that the body 32 is generally electrically conductive. For example, in some embodiments, physical contact between the edge 26 of the corresponding printed circuit board 16 and the wall surface(s) 44, 46, and/or 48 and/or one or more spring members 18 (described below) may electrically connect the corresponding printed circuit board 26 to the body 32 to provide an electrical ground path between the corresponding printed circuit board 16 and a ground source (e.g., a side wall 20) of the enclosure 12 using the body 32 of the card guide 14.

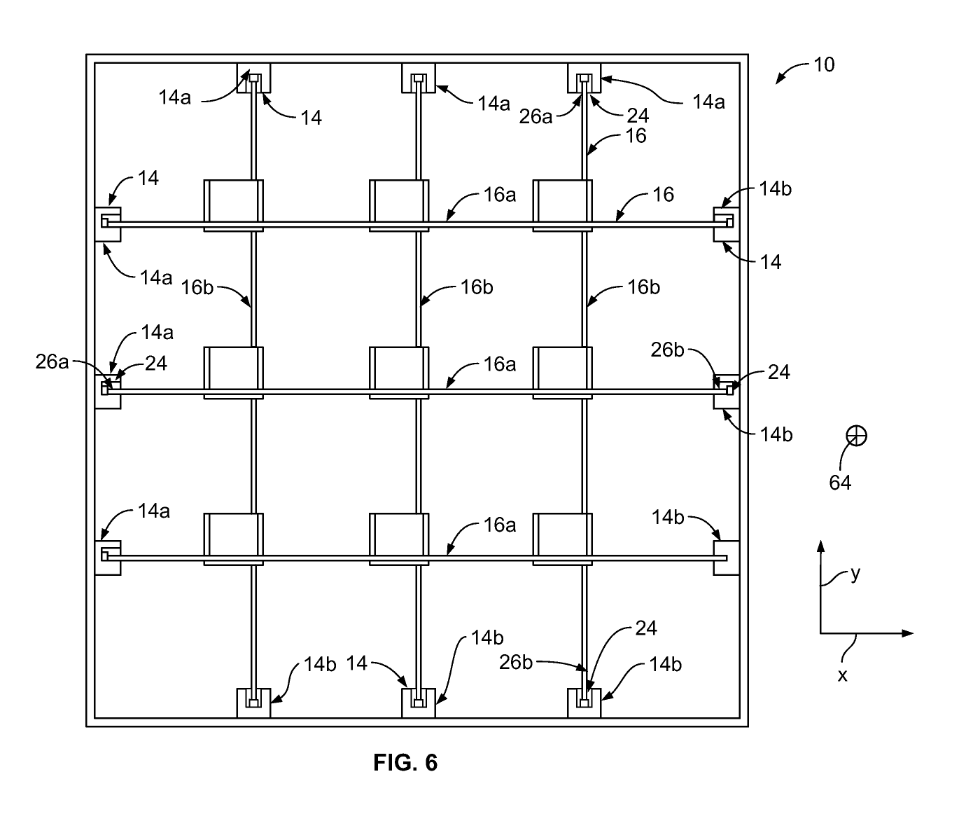

As briefly described above, the card guide 14 includes spring members 18 that approximately center the corresponding printed circuit board 16 along two different, non-parallel, axes (e.g., the x and y axes shown in FIGS. 1 and 6). Specifically, the card guide 14 includes spring members 18a that extend along the side wall 38 into the slot 24. The card guide 14 also includes spring members 18b that extend along the side wall 40 into the slot 24. The spring members 18b are not shown in FIG. 4. The spring members 18a and 18b oppose each other within the slot 24 such that the spring members 18a and 18b are configured to exert opposing spring forces on the corresponding edge 26 of the corresponding printed circuit board 16.

Specifically, when the corresponding edge 26 of the corresponding printed circuit board 16 is received within the slot 24, each spring member 18a is configured to engage in physical contact with a side 52 (shown in FIG. 5) of the corresponding edge 26 such that the spring member 18a biases the printed circuit board 12 in a direction 54. In other words, each spring member 18a is configured to exert a spring force on the side 52 of the corresponding edge 26 that acts in the direction 54. Similarly, each spring member 18b is configured to engage in physical contact with a side 56 (shown in FIG. 5) of the corresponding edge 26 that is opposite the side 54 such that the spring member 18a exerts a spring force on the side 56 of the corresponding edge 26. Each spring member 18b thus biases the printed circuit board 12 in a direction 58 that is opposite the direction 54. As will be described below, the opposing spring forces exerted on the corresponding edge 26 of the corresponding printed circuit board 16 by the spring members 18a and 18b cooperate to approximately center the corresponding edge 26 along the width W of the slot 24.

The card guide 14 may include any number of the spring members 18a and any number of the spring numbers 18b. Although shown as spring beams, each of the spring members 18a and each of the spring members 18b additionally or alternatively may include any other structure, geometry, and/or the like that enable the spring members 18a and/or 18b to function as described and illustrated herein. The size of and/or spring force provided by each spring member 18a and each spring member 18b may be selected based on a weight of the corresponding printed circuit board 16. In the illustrated embodiment, each of the spring members 18a and each of the spring members 18b is integrally formed with a single, unitary construction with the body 32 of the card guide 14. But, one or more of the spring members 18a and/or one or more of the spring members 18b may be a discrete component from the body 32 (which may or may not be fabricated from the same material(s) and/or have the same properties as the body 32). Each of the spring members 18a and each of the spring members 18b may be fabricated from any material(s), such as, but not limited to, a polymer, a plastic, a metal, a composite, and/or the like.

Although shown as being aligned along the length L₁ of the slot 24, one or more of the spring members 18a may not be aligned with any of the spring members 18b along the length L₁ of the slot 24, and vice versa. In other words, the spring members 18a may have any other pattern along the length of the side wall surface 44 of the slot 24 and the spring members 18b may have any other pattern along the length of the side wall surface 46 of the slot 24, wherein the patterns may or may not be the same, complementary, aligned with each other, and/or the like. Each of the spring members 18a and each of the spring members 18b may be referred to herein as a “first”, “second”, and/or “third” spring member. Each of the sides 52 and 56 of the edge 26 of the printed circuit board 16 may be referred to herein as a “first” and/or a “second” side. Each of the directions 54 and 58 may be referred to herein as a “first”, “second”, and/or “third” direction.

As should be appreciated from the above description and will be described in more detail below, the opposing spring forces exerted by the spring members 18a and 18b cooperate to approximately center the corresponding printed circuit board 16 along an axis (e.g., the x axis or the y axis). The card guide 14 also includes one or more spring members 18c that cooperate with the spring member(s) 18c of one or more other card guides 14 to approximately center the corresponding printed circuit board 16 along another axis (e.g., the x axis or they axis).

Specifically, the card guide 14 includes spring members 18c that extend along the bottom wall 42 into the slot 24. When the corresponding edge 26 of the corresponding printed circuit board 16 is received within the slot 24, each spring member 18c is configured to engage in physical contact with an edge surface 60 (shown in FIG. 5) of the corresponding edge 26 that extends between (i.e., interconnects) the sides 52 and 56 of the corresponding edge 26. The spring member 18c thus biases the printed circuit board 12 in a direction 62 by exerting a spring force on the edge surface 60 that acts in the direction 62. As shown in FIGS. 2-4, the direction 62 extends approximately perpendicular to each of the directions 54 and 58. As will be described below, the spring members 18c cooperate with the spring member(s) 18c of one or more other card guides 14 to approximately center the corresponding printed circuit board 16 between the card guides 14.

The card guide 14 may include any number of the spring members 18c. Although shown as spring beams, each of the spring members 18c additionally or alternatively may include any other structure, geometry, and/or the like that enable the spring members 18c to function as described and illustrated herein. The size of and/or spring force provided by each spring member 18c may be selected based on a weight of the corresponding printed circuit board 16.

In the illustrated embodiment, each of the spring members 18c is integrally formed with a single, unitary construction with the body 32 of the card guide 14. But, one or more of the spring members 18c may be a discrete component from the body 32 (which may or may not be fabricated from the same material(s) and/or have the same properties as the body 32). Each of the spring members 18c may be fabricated from any material(s), such as, but not limited to, a polymer, a plastic, a metal, a composite, and/or the like. The spring members 18c may have any other pattern along the length of the bottom wall surface 48. Each of the spring members 18c may be referred to herein as a “first”, “second”, and/or “third” spring member. The direction 62 may be referred to herein as a “first” and/or a “third” direction.

Referring again to FIG. 1, the printed circuit boards 16 are configured to be loaded into the enclosure 12 along insertion axes 64. Specifically, the edges 26 of the printed circuit boards 16 are configured to be loaded into the corresponding slots 24 along corresponding insertion axes 64. As shown in FIG. 1, the circuit boards 16 have been loaded into the enclosure 12 such that the edges 26 are held within the corresponding slots 24 of the corresponding card guides 14.

FIG. 5 is an elevational view of a portion of the electronic system 10 illustrating an edge 26 of a printed circuit board 16 as held by the corresponding card guide 14. As shown in FIG. 5, when the edge 26 is received within the slot 24 of the card guide 14, the spring members 18a are engaged in physical contact with the side 52 of the edge 26 such that the spring members 18a exert the spring forces on the side 52 that bias the printed circuit board 12 in the direction 54. Moreover, the spring members 18b are engaged in physical contact with the side 56 of the edge 26 such that the spring members 18b exert the spring forces on the side 56 that bias the printed circuit board 16 in the direction 58 (which is opposite the direction 54). The opposing spring forces exerted on the edge 26 in the opposing directions 54 and 58 by the spring members 18a and 18b cooperate to approximately center the edge 26 along the width W of the slot 24. As can be seen in FIG. 5, each of the directions 54 and 58 extends approximately perpendicular to the printed circuit board 16 when the edge 26 is received within the slot 24. The directions 54 and 58 also each extend approximately perpendicular to the insertion axis 64.

As shown in FIG. 5, the spring members 18c are engaged in physical contact with the edge surface 60 of the edge 26 such that the spring members 18c exert the spring forces on the edge surface 60 that bias the printed circuit board 12 in the direction 62. As will be shown in FIG. 6, the spring members 18c cooperate with the spring member(s) 18c of one or more other card guides 14 to approximately center the printed circuit board 16 between the card guides 14. As described above and shown in FIG. 5, in the illustrated embodiment, the direction 62 extends approximately perpendicular to each of the directions 54 and 58 such that the spring members 18 bias the printed circuit board 16 in two different directions that are not approximately parallel with each other. As can also be seen in FIG. 5, the direction 62 extends approximately parallel to the printed circuit board 16 and approximately perpendicular to the insertion axis 64 when the edge 26 is received within the slot 24.

FIG. 6 is an elevational view of the electronic system 10 illustrating the printed circuit boards 16 as held by the card guides 14. When the edges 26a and 26b of the printed circuit boards 16 are held within the slots 24 of the card guides 14a and 14b, respectively, the spring members 18a and 18b (shown in FIGS. 2-5) approximately center the corresponding printed circuit board 16 along the width W (shown in FIGS. 2, 3, and 5) of the slot 24 and thereby along a first axis. In the illustrated embodiment, the spring members 18a and 18b approximately center the printed circuit boards 16a along the y axis and the printed circuit boards 16b along the x axis.

As shown in FIG. 6, the spring members 18c (shown in FIGS. 2-5) of the card guides 14a cooperate with the spring members 18c of the corresponding card guides 14b to approximately center the corresponding printed circuit board 16 between the card guides 14a and 14b. The spring members 18c of corresponding card guides 14a and 14b thereby approximately center the corresponding printed circuit board 16 along a second axis that is not approximately parallel with the first axis. In the illustrated embodiment, the spring members 18c approximately center the printed circuit boards 16a along the x axis and the printed circuit boards 16b along they axis.

Accordingly, the card guides 14 are configured to approximately center each printed circuit board 16 along two different, non-parallel axes (i.e., the x and y axes in the illustrated embodiment). In the illustrated embodiment, the x and y axes extend approximately perpendicular to each other, but the two different, non-parallel axes (i.e., the x and y axes in the illustrated embodiment) may extend at any other non-parallel angle relative to each other. As shown in FIG. 6, in the illustrated embodiment, the x and y axes each extend approximately perpendicular to the insertion axis 64, the x axis extends approximately parallel to the printed circuit boards 16a and approximately perpendicular to the printed circuit boards 16b, and the y axis extends approximately perpendicular to the printed circuit boards 16a and approximately parallel to the printed circuit boards 16b.

The embodiments described and/or illustrated herein provide card guides that facilitate (i.e., ease) aligning printed circuit boards for installation within an electronic system. For example, by approximately centering a printed circuit board 16 along two different, non-parallel axes, the card guides 14 may reduce the size (e.g., as compared to the requirements of at least some known electronic systems) of tapered guide devices (not shown; e.g., guide pins, guide posts, guide openings, guide slots, and/or the like) that is required to align the printed circuit boards 16 for installation into the electronic system 10. For example, the spring elements 18a, 18b, and/or 18c may counteract the weight of the printed circuit board 16 and thereby prevent the printed circuit board 16 from shifting against the wall surface(s) 44, 46, and/or 48 (shown in FIGS. 2-5) during loading of the printed circuit board 16. The embodiments described and/or illustrated herein may reduce cost, may reduce the size of tapered guide devices, may reduce the size of a printed circuit board, may reduce the size of an enclosure, may increase the number of printed circuit boards that can be held by an enclosure, and/or the like.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112(f), unless and until such claim limitations expressly use the phrase “means for” followed by a statement of function void of further structure.

What is claimed is:

1. A card guide for holding a printed circuit board within an enclosure, the card guide comprising:
a body extending a length from a front end to a rear end, the body comprising a slot extending through at least a portion of the length of the body, the slot being configured to receive an edge of the printed circuit board therein;
a first spring member extending into the slot, the first spring member being configured to engage in physical contact with the edge of the printed circuit board within the slot such that the first spring member biases the printed circuit board in a first direction; and
a second spring member extending into the slot, the second spring member being configured to engage in physical contact with the edge of the printed circuit board within the slot such that the second spring member biases the printed circuit board in a second direction that extends approximately perpendicular to the first direction.

2. The card guide of claim 1, further comprising a third spring member extending into the slot, wherein the third spring member is configured to engage in physical contact with the edge of the printed circuit board within the slot such that the third spring member biases the print circuit board in a third direction that is opposite the second direction.

3. The card guide of claim 1, wherein the first direction extends approximately parallel with the printed circuit board and the second direction extends approximately perpendicular to the printed circuit board when the edge of the printed circuit board is received within the slot.

4. The card guide of claim 1, wherein the edge of the printed circuit board is configured to be loaded into the slot along an insertion axis, the first and second directions each extending approximately perpendicular to the insertion axis.

5. The card guide of claim 1, wherein the card guide is a first card guide and the first spring member is configured to cooperate with a second card guide to approximately center the printed circuit board between the first and second card guides.

6. The card guide of claim 1, further comprising a third spring member extending into the slot, wherein the third spring member is configured to engage in physical contact with the edge of the printed circuit board within the slot such that the second and third spring members are configured to approximately center the edge of the printed circuit board within a width of the slot.

7. The card guide of claim 1, wherein the edge of the printed circuit board includes opposite sides and an edge surface that extends between the sides, the second spring member being configured to engage in physical contact with a corresponding one of the sides of the edge of the printed circuit board to bias the printed circuit board in the second direction, the first spring member being configured to engage in physical contact with the edge surface of the edge of the printed circuit board to bias the print circuit board in the first direction.

8. The card guide of claim 1, wherein the slot of the body includes opposing side wall surfaces and a bottom wall surface that extends between the side wall surfaces, the first spring member extending along the bottom wall surface, the second spring member extending along one of the side wall surfaces.

9. The card guide of claim 1, wherein at least one of the first spring member or the second spring member comprises a spring beam.

10. The card guide of claim one, wherein at least one of the first spring member or the second spring member is integrally formed with a single, unitary construction with the body.

11. The card guide of claim 1, wherein at least one of the body, the first spring member, or the second spring member is electrically conductive and is configured to provide an electrical ground path between the printed circuit board and a ground source.

12. A card guide for holding a printed circuit board having an edge that includes opposite first and second sides and an edge surface that extends between the first and second sides, the card guide comprising:
a body extending a length from a front end to a rear end, the body comprising a slot extending through at least a portion of the length of the body, the slot being configured to receive the edge of the printed circuit board therein, wherein the slot comprises opposing first and second side wall surfaces and a bottom wall surface that extends between the first and second side wall surfaces;
first and second spring members extending along the first and second side wall surfaces, respectively, of the slot, wherein the first and second spring members are configured to exert a spring force on the first and second sides, respectively, of the edge of the printed circuit board; and
a third spring member extending along the bottom wall surface of the slot, wherein the third spring member is configured to exert a spring force on the edge surface of the edge of the printed circuit board.

13. The card guide of claim 12, wherein the slot has a width defined between the first and second side wall surfaces, the first and second spring members being configured to approximately center the edge of the printed circuit board within the width of the slot.

14. The card guide of claim 12, wherein the card guide is a first card guide and the third spring member is configured to cooperate with a second card guide to approximately center the printed circuit board between the first and second card guides.

15. The card guide of claim 12, wherein the spring forces exerted by the first and second spring members are configured to act in respective first and second directions that are opposite each other, each of the first and second directions extending approximately perpendicular to the printed circuit board when the edge of the printed circuit board is received within the slot, the spring force exerted by the third spring member being configured to act in a third direction that extends approximately parallel to the printed circuit board when the edge of the printed circuit board is received within the slot.

16. The card guide of claim 12, wherein at least one of the first spring member, the second spring member, or the third spring member is integrally formed with a single, unitary construction with the body.

17. An assembly comprising:
a printed circuit board having opposite edges; and
first and second card guides each comprising:
a slot configured to receive a corresponding one of the edges of the printed circuit board therein;
first spring members that extend within the slot and are configured to exert opposing spring forces on the corresponding edge of the printed circuit board that cooperate to approximately center the corresponding edge of the printed circuit board within the slot; and
a second spring member that extends within the slot and is configured to exert a spring force on the corresponding edge of the printed circuit board, wherein the spring forces exerted by the second spring members of the first and second card guides oppose each other and cooperate to approximately center the printed circuit board between the first and second card guides.

18. The assembly of claim 17, wherein each of the edges of the printed circuit board comprises opposite sides and an edge surface that extends between the sides, the first spring members of each of the first and second card guides being configured to exert the spring force on a corresponding one of the sides of the corresponding edge of the printed circuit board, the second spring member of each of the first and second card guides being configured to exert the spring force on the edge surface of the corresponding edge of the printed circuit board.

19. The assembly of claim 17, wherein the slot of each of the first and second card guides includes opposing first and second side wall surfaces and a bottom wall surface that extends between the first and second side wall surfaces, at least one of the first spring members of each of the first and second card guides extending along the first side wall surface of the slot, at least one of the first spring members of each of the first and second card guides extending along the second side wall surface of the slot, the second spring member of each of the first and second card guides extending along the bottom wall surface of the slot.

20. The assembly of claim 17, wherein at least one of the first spring members or at least one of the second spring members is integrally formed with a single, unitary construction with a body of the corresponding first or second card guide.
